(19) United States
(12) Patent Application Publication
(10) Pub. No.: US 2007/0052078 A1
(43) Pub. Date: Mar. 8, 2007

(54) MATRIX PACKAGE SUBSTRATE STRUCTURE, CHIP PACKAGE STRUCTURE AND MOLDING PROCESS THEREOF

(76) Inventor: Jen-Chieh Kao, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,968

(22) Filed: Dec. 13, 2005

(30) Foreign Application Priority Data
Sep. 5, 2005 (TW) 94130268

(51) Int. Cl. H01L 23/02

(52) U.S. Cl. 257/685

(57) ABSTRACT

A matrix package substrate molding process is provided. First, a matrix package substrate with a plurality of package units for disposing chips on the package units is provided. Next, an encapsulation mold is disposed on each of the package units. The mold has a plurality of mold cavities arranged as branches to correspondingly accommodate a chip. When the encapsulation is filled into the mold and flows into the cavities by branch, the chips on the branch are covered by the encapsulation. After curing the encapsulation, the mold is lifted off to complete the package operation. Accordingly, the processing time and cost are saved.

### CROSS-REFERENCE TO RELATED APPLICATION

This application claims the priority benefit of Taiwan application serial no. 94130268, filed on Sep. 5, 2005. All disclosure of the Taiwan application is incorporated herein by reference.

### BACKGROUND OF THE INVENTION

1. Field of Invention

The present invention relates to a chip package structure and a molding process thereof. More particularly, the present invention relates to a chip package structure using a matrix package substrate and a molding process thereof.

2. Description of Related Art

A matrix package process includes such packaging steps as chip bounding, encapsulating, and cutting procedures on a large circuit substrate. Wherein, bonding pads of chips can be electrically connected with the substrates of grid-shaped package units through gold wires or tin lead bumps. Next, the periphery of each chip is covered by a high-temperature cured encapsulation, e.g. epoxy resin. After the encapsulation is cooled and shaped, along the predetermined path, the cutting tool divides the substrate of each package unit into separate chip package structures. In the molding process, for the chip package structure of a single specification product, the use of the matrix package process can increase the packaging speed, decrease the packaging time and cost, so that the matrix package process is mostly used to increase throughput.

FIGS. 1 to 4 are schematic drawings respectively illustrating a conventional matrix package substrate molding process. First, referring to FIG.1, a plurality of chips 100 are respectively disposed on substrates 110 of each package unit, and then the bonding pads (not illustrated) of the chips 100 and the bonding pads 112 of the substrate 110 are electrically connected with each other through a plurality of wires 120. Next, referring to FIG.2, an encapsulation mold 20 is disposed on the substrate 110, and the mold cavities 22 of the encapsulation mold 20 correspondingly cover all the chips 100 to form an independent filling space. Then, referring to FIG.3, the melted encapsulation 1 30 is filled into the mold cavities 22 and the air in the mold cavities 22 is expelled by pressure. When the cured encapsulation 130 is disengaged from the encapsulation mold 20 to be shaped up, the chips 100 and the wires 120 are sealed by the encapsulation 130. Last, referring to FIG.4, the substrates 110 of each package unit 10 are cut into separate chip package structures 140.

Note that the substrates 110 of the package unit 10 is easy to be warped when heated, so that the encapsulation mold 20 cannot be tightly connected with the substrate 110 with imperfect evenness, which can make the encapsulation 130 flow out through the gaps and remain between the adjacent substrates 110 to affect the process yield. In addition, when the air in the mold cavities 22 cannot be expelled smoothly, the encapsulation 130 would have remaining air bubbles which could affect the package reliability.

### SUMMARY OF THE INVENTION

Accordingly, the present invention is directed to provide a matrix package substrate structure which can avoid remaining air bubbles in the encapsulation so as to increase the package reliability.

The present invention is also directed to provide a matrix package substrate molding process to improve the tightness between an encapsulation mold and a substrate so as to increase the process yield factor.

The present invention provides a matrix package substrate structure including a plurality of package units, a plurality of first contacts, a plurality of second contacts, a solder mask, a plurality of chips, and a plurality of encapsulations. Each package unit has a first surface, a second surface and at least a substrate of a circuit layer. The first contacts are disposed around the first surface of each package unit while the second contacts are disposed around the second surface of each package unit. In addition, the solder mask covers the package units and exposes the first contacts and the second contacts. The chips are disposed on each package unit and electrically connected with the first contacts and the second contacts through the circuit layer of the package unit. Besides, the encapsulations are arranged as branches on each package unit, wherein the encapsulations respectively cover the chips of each branch.

According to a preferred embodiment of the present invention, the aforementioned encapsulations are filled through, for example, an encapsulation mold having a plurality of mold cavities accommodating the chips of each branch. In addition, the encapsulation mold has, for example, a general channel connected with the mold cavities of each branch. The encapsulations flow into the mold cavities of each branch through the general channel, and then are cured to be shaped. Besides, the encapsulations are, for example, transparent encapsulations.

The present invention also provides a matrix package substrate molding process. First, a matrix package substrate with a plurality of package units is provided. Next, a plurality of chips are disposed on the package units. Then, an encapsulation mold is disposed on the package units, wherein the encapsulation mold has a plurality of mold cavities arranged as branches correspondingly to accommodate the chips. Afterwards, an encapsulation is filled into the encapsulation mold and flows into the mold cavities by the branches to cover the chips of each branch. Last, the encapsulation is cured and the encapsulation mold is lifted off.

According to a preferred embodiment of the present invention, the aforementioned encapsulation mold for example has a general channel connecting the mold cavities of each branch, and the encapsulations flow into the mold cavities of each branch through the general channel, then are cured to be shaped.

According to a preferred embodiment of the present invention, the aforementioned matrix package substrate process further includes cutting the matrix package substrate to form separate package units.

The present invention also provides a chip package structure including a substrate, a plurality of first contacts, a plurality of second contacts, a solder mask, a chip, and an encapsulation. The substrate has a first surface, a second surface and at least a circuit layer. The first contacts are disposed on the first surface while the second contacts are disposed on the second surface, and the second contacts are electrically connected with the first contacts. In addition, the solder mask covers the first surface and the second surface, and respectively exposes the first contacts and the second contacts. The chip is disposed on the first surface and electrically connected with the first contacts and the second contacts through the circuit layer of the substrate, then is covered by the encapsulation.

According to a preferred embodiment of the present invention, the aforementioned chip is electrically connected with the circuit layer of the substrate by way of, for example, wire bonding. Besides, the chip is electrically connected with the circuit layer of the substrate by way of, for example, flip chip bonding. In addition, the encapsulation is for example a transparent colloid.

The present invention uses a novelty encapsulation mold with mold cavities arranged as branches and correspondingly covering around each chip, and the tightness between encapsulations and substrates is desired. In addition, when flowing into mold cavities arranged as branches through channels, colloid can expel the air in mold cavities through channels, so that the air will not remain in the colloid and the package reliability can be increased.

In order to make the aforementioned and other objects, features and advantages of the present invention comprehensible, a preferred embodiment accompanied with FIGures is described in detail below.

### BRIEF DESCRIPTION OF THE DRAWINGS

FIGS. 1 to 4 are schematic drawings respectively illustrating a conventional matrix package substrate molding process.

FIGS. 5 to 10 are flow charts of a matrix package substrate molding process of a preferred embodiment of the present invention.

FIG. 11A and FIG. 11B are a top view and a side view of the chip package structure of the present invention.

FIG. 12 is a solid schematic drawing of a matrix package substrate structure of a preferred embodiment of the present invention.

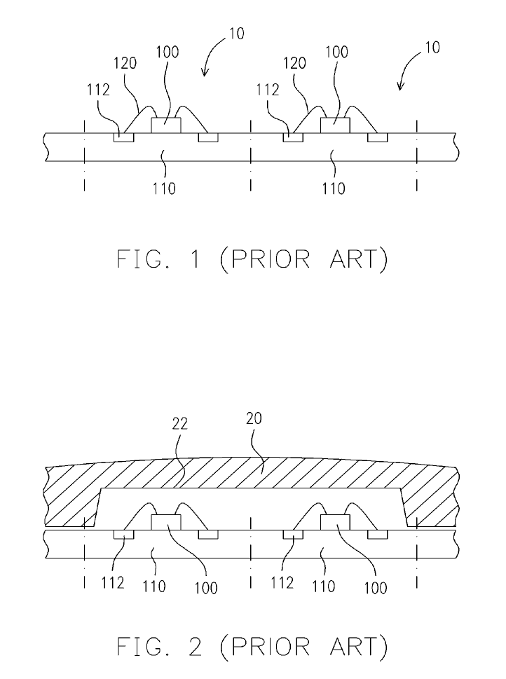

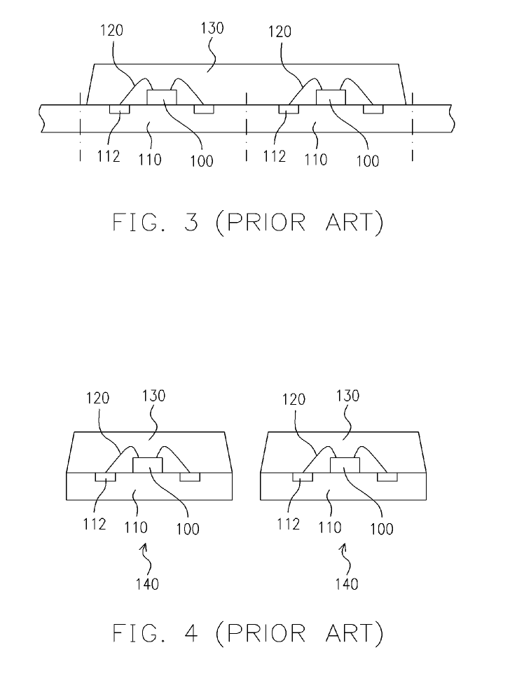

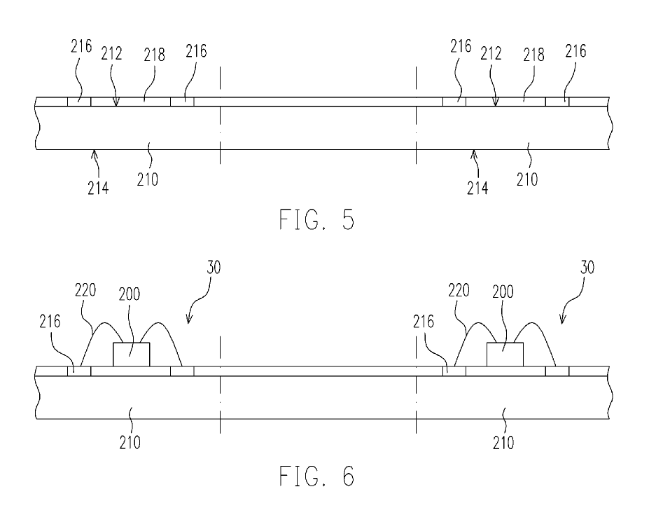

### DESCRIPTION OF EMBODIMENTS

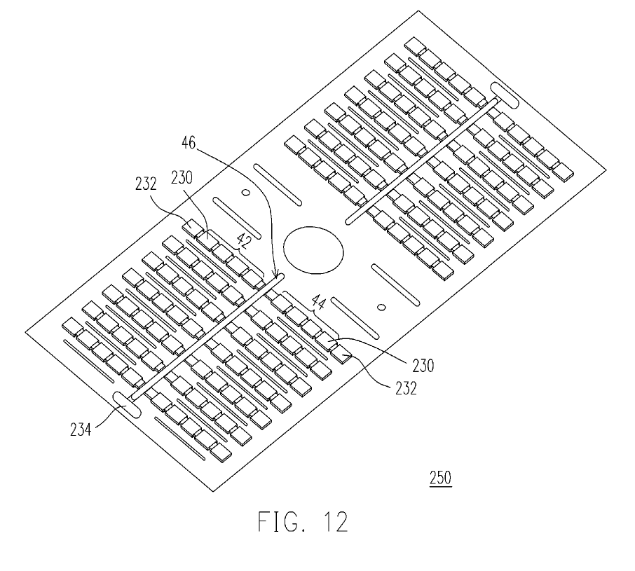

FIGS. 5 to 10 are flow charts of a matrix package substrate molding process of a preferred embodiment of the present invention. First of all, referring to the cross-sectional view of the matrix package substrate in FIG. 5, the circuit layer (not illustrated) on the first surface 212 and the second surface 214 of each substrate 210 is isolated by, for example, the solder mask 218, and only the bonding pads of the chips connected with the ends of the circuit layer are exposed in the openings of the solder mask 218 for the connection of the chip signals. Referring to FIG. 11B, in the present embodiment, a plurality of first contacts 222 and a plurality of second contacts 224 can be further disposed on the edge of each substrate 210, and the chips 200 are electrically connected with the first contacts 222 and the second contacts 224 through the circuit layer. Therefore, the signals of the chips 200 can be transmitted to other electronic devices through the first contacts 222 and the second contacts 224.

Next, referring to the chip bonding process in FIG. 6, a plurality of chips 200 are disposed on the substrate 210 of each package unit 30, wherein the chips 200 are electrically connected with the circuit layer of the substrate 210 or bonding pads 216 through, for example, thermo-compression bonding of the wires 220. Besides, the chips 200 can also be electrically connected with the circuit layer of the substrate 210 or bonding pads 216 through bumps (not illustrated) of flip chip bonding, or through other ripe chip bonding technologies.

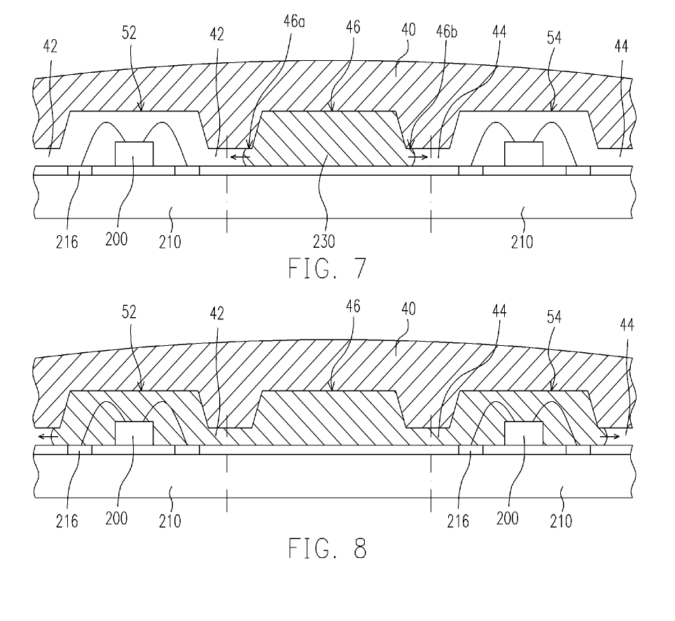

Next, referring to the encapsulation process in FIG. 7, an encapsulation mold 40 covers the substrates 210 of a plurality of package units 30. The encapsulation mold 40 has at least two colloid channels 42 and 44, wherein the channels, like branches, are connected to the exits 46a and 46b of a general channel 46. The colloid channel 42 is a branch channel consisting of a plurality of mold cavities 52 (only one of them illustrated) connected with each other. Similarly, another colloid channel 44 also consists of a plurality of mold cavities 54 (only one illustrated) connected with each other. The encapsulation 230 can flow into the two channels 42 and 44 with smaller calibers from the general channel 46 with a larger caliber, and then fully fill each of the mold cavities 52 and 54 in sequence. When the encapsulation 230 heated to melting temperature begins to flow into the channels 42 and 44, the air in the first mold cavities 52 and 54 close to the general channel 46 is pressed backwards.

Next, referring to FIG. 8, after fully filling the first mold cavities 52 and 54, the encapsulation 230 continues flowing through channels and presses the air in the second mold cavities (not illustrated). Thus, the air is pressed backwards until it gets the last mold cavities (not illustrated) and then it is expelled. In the design of the mold cavities, the last mold cavities are, for example, used to dispose remaining encapsulation 232 (as shown in FIG. 12) instead of the chips 200. The same design can also be used in the end of the general channel 46, so that the remaining encapsulation (as shown in FIG. 12) not flowing into the channels 42 and 44 lies in the mold cavity (not illustrated) of the end of the general channel 46. In the process of FIG. 8, after the filling of the encapsulation 230 is finished, the encapsulation mold 40 is heated to the temperature to cure the encapsulation, which makes the encapsulation produce bonding for a curing process.

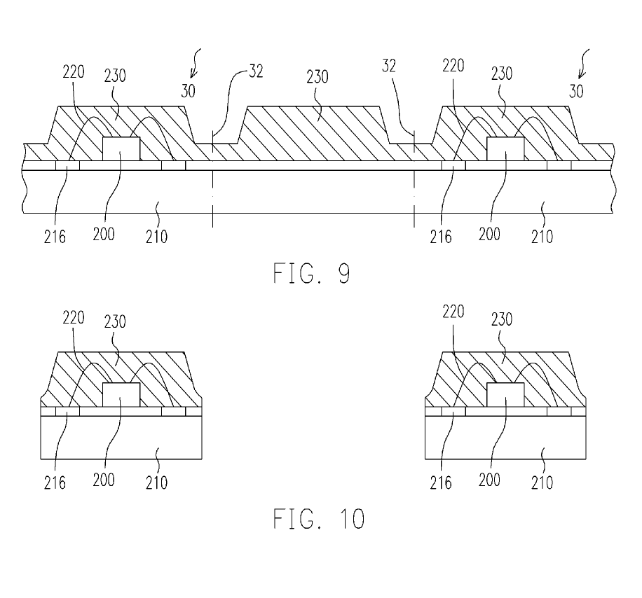

Then, referring to the process in FIG. 9, because the cured encapsulation 230 has smaller viscosity, the mold release capability between the encapsulation 230 and the encapsulation mold 40 is enhanced, so that the operation of mold release can be smoothly finished and then the encapsulation mold 40 can be lifted off.

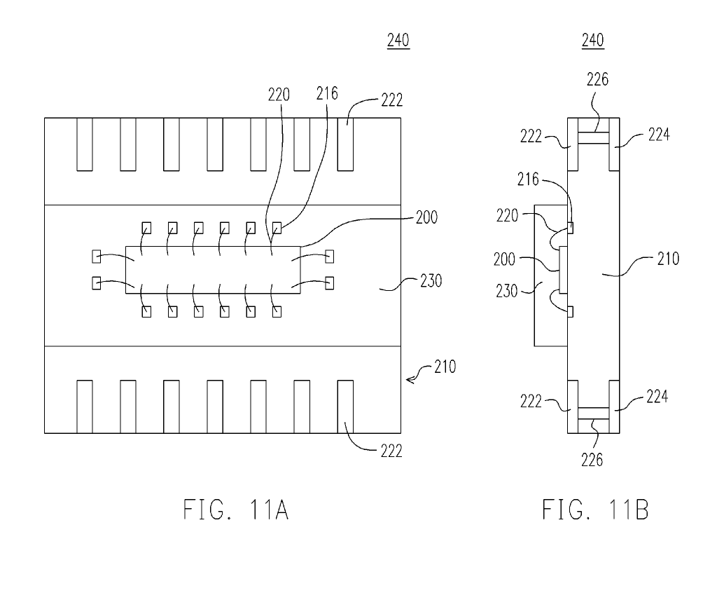

Last, referring to the cutting process in FIG. 10, the substrate 210 of each package unit is cut by a cutting tool along a predetermined cutting paths 32 (as shown in FIG. 9), wherein the cutting paths 32 lie between the adjacent substrates 210. Referring to FIG. 11B, when the first contacts 222 and the second contacts 224 of the substrate 210 are to be exposed on the side edges of the substrate 210, the edges of the cutting paths (not illustrated) are aligned with the outer sides of the first contacts 222 and the second contacts 224, so that the cutting tool can cut off the first contacts 222 and the second contacts 224 arranged in order to form the chip package structure 240 shown in FIG. 11A and FIG. 11B at last.

FIG. 11A and FIG. 11B are a top view and a side view of the chip package structure of the present invention. The first contacts 222 and the second contacts 224 are disposed on the two sides of the substrate 210. The chip 200 and the wires 220 are covered by the encapsulation 230, and the chip 200 is electrically connected with the substrate 210. In the present embodiment, the first contacts 222 and the second contacts 224 are disposed on the corresponding surfaces of the substrate 210 and electrically connected with each other through conducting poles 226 or conducting holes. Bonding balls (not illustrated) or other bonding structures can be selectively disposed on the first contacts 222 or second contacts 224 for electrically connecting outside electronic devices or stacking packages. In addition, the encapsulation 230 is, for example, a transparent colloid while the chip 200 is, for example, a CMOS sensitive chip or a charge coupled device. When a light radiates the chip 200 through transparent encapsulatio 230, the optical signal is converted into an electronic signal through a photoelectric transferring element and output in the form of an image. The material of the encapsulatio 230 and the type of the chip 200 are not limited in the present embodiment.

FIG. 12 is a solid schematic drawing of a matrix package substrate structure of a preferred embodiment of the present invention. Referring to FIG. 7, FIG. 8, FIG. 9, and FIG. 12, when the encapsulation 230 flows into the channels 42 and 44 through the strip general channel 46 perpendicular and crossing the channels 42 and 44, the encapsulatio 230 covers the chips 200 of each branch and is cured to be shaped. Last, the encapsulation mold 40 is lifted off to finish the matrix package substrate structure 250 in FIG. 12. Because the mold cavities 52 and 54 of the encapsulation mold 40 are arranged as branches on each channel 42 and 44, air bubbles are unlikely to remain in the encapsulatio 230, so that the reliability of the process can be increased. Due to the improvement of the encapsulation mold 40, even if the substrate 210 is warped when heated and has imperfect evenness, the encapsulatio 230 still can flow into the mold cavities 52 and 54 through channels and is not likely to flow out through the gaps to leave over the substrate 210, so that the yield of the process can be increased.

In summary, the present invention uses a novelty encapsulation mold with mold cavities arranged as branches correspondingly covering around each chip, and the tightness between encapsulation molds and substrates is desired. In addition, when flowing into mold cavities arranged as branches through channels, an encapsulatio can expel the air in mold cavities through channels, so that the air cannot remain in the encapsulatio and the package reliability can be increased. Besides, due to the improvement of the design of mold cavities, the process time is reduced, so that the productive capacity can be increased.

The present invention is disclosed above with its preferred embodiments. It is to be understood that the preferred embodiment of present invention is not to be taken in a limiting sense. It will be apparent to those skilled in the art that various modifications and variations can be made to the structure of the present invention without departing from the scope or spirit of the invention. The protection scope of the present invention is in accordant with the scope of the following claims and their equivalents.

What is claimed is:

1. A matrix package substrate structure, comprising:
a plurality of package units having a first surface, a second surface, and at least a substrate of a circuit layer;
a plurality of first contacts disposed around the first surface of each package unit;
a plurality of second contacts disposed around the second surface of each package unit;
a solder mask covering the package units and exposing the first contacts and the second contacts;
a plurality of chips disposed on the package units and electrically connected with the first contacts and the second contacts through the circuit layers of the package units; and
a plurality of encapsulations arranged as branches on the package units, wherein the encapsulations respectively cover the chips on each branch.

2. The matrix package substrate structure of claim 1, wherein the encapsulations are filled through an encapsulation mold having a plurality of mold cavities respectively accommodating the chips of each branch.

3. The matrix package substrate structure of claim 2, wherein the encapsulation mold has a general channel connected with the mold cavities of each branch; the encapsulations flow into the mold cavities of each branch through the general channel, and are cured to be shaped.

4. The matrix package substrate structure of claim 1, further comprising a plurality of wires, wherein the chips are electrically connected to the package units through the wires.

5. The matrix package substrate structure of claim 4, wherein the wires are respectively covered by the encapsulations.

6. The matrix package substrate structure of claim 1, further comprising a plurality of bumps, wherein the chips are electrically connected to the package units through the bumps.

7. The matrix package substrate structure of claim 6, wherein the bumps are respectively covered by the encapsulations.

8. The matrix package substrate structure of claim 1, wherein the encapsulations are transparent encapsulations.

9. A matrix package substrate molding process, comprising:
providing a matrix package substrate with a plurality of package units;
disposing a plurality of chips on the package units;
laying an encapsulation mold on the package units, wherein the encapsulation mold has a plurality of mold cavities, arranged as branches, to correspondingly accommodate the chips;
filling an encapsulation into the encapsulation mold, wherein the encapsulation flows into the mold cavities by the branches to cover the chips of each branch; and
curing the encapsulation and lifting off the encapsulation mold.

10. The matrix package substrate molding process of claim 9, wherein the encapsulation mold has a general channel connected with the mold cavities of each branch; the encapsulation flows into the mold cavities of each branch through the general channel, and is cured to be shaped.

11. The matrix package substrate molding process of claim 9, further comprising cutting the matrix package substrate to form separate package units.

12. A chip package structure, comprising:
a substrate having a first surface, a second surface, and at least a circuit layer;
a plurality of first contacts disposed on the first surface of the substrate;
a plurality of second contacts disposed on the second surface of the substrate, and electrically connected with the first contacts;
a solder mask covering the first surface and the second surface, and respectively exposing the first contacts and the second contacts;
a chip disposed on the first surface, and electrically connected with the first contacts and the second contacts through the circuit layer of the substrate; and
an encapsulation covering the chip.

13. The chip package structure of claim 12, wherein the chip is electrically connected with the circuit layer of the substrate by way of wire bonding.

14. The chip package structure of claim 12, wherein the chip is electrically connected with the circuit layer of the substrate by way of flip chip bonding.

15. The chip package structure of claim 12, wherein the encapsulation is a transparent colloid.
